(19) United States
(12) Patent Application Publication
(10) Pub. No.: US 2015/0002174 A1
(43) Pub. Date: Jan. 1, 2015

(54) TAPERED MUTUAL CAPACITIVE SENSING PATTERN FOR SINGLE TOUCH

(71) Applicant: TEXAS INSTURMENTS INCORPORATED, Dallas, TX (US)

(72) Inventor: Tao Peng, Nashua, NH (US)

(21) Appl. No.: 14/138,233

(22) Filed: Dec. 23, 2013

(30) Foreign Application Priority Data
Jul. 1, 2013 (CN) PCT/CN2013/078603

(51) Int. Cl. G01R 27/26

(52) U.S. Cl. CPC G01R 27/2605
USPC 324/661

(57) ABSTRACT

A system comprises a plurality of receiving electrode sets, each of the plurality of receiving electrodes being defined by a coupled intersecting diagonal bar; a plurality of sets of transmitting electrodes, each set of the transmitting electrodes having: at least a first electrode on a first side of its corresponding receiving electrode, and a second electrode on a second side of its corresponding receiving electrode; and a first AC signal generator to generate a signal on the plurality of electrode sets of transmitting electrodes to be received by the receiving electrodes.

### TECHNICAL FIELD

This Application is directed, in general, to a single-touch mutual capacitive sensing and, more specifically, to a single touch mutual capacitive sensing that uses a tapered capacitive sensing pattern.

### BACKGROUND

Mutual capacitive sensing can be generally defined as wherein an object (finger, conductive stylus) alters the mutual coupling between row and column electrodes, which are typically scanned sequentially.

FIG. 1A illustrates a representative prior-art multi-touch prior art mutual capacitive sensing network 100. The sensing network 100 includes an electrode sensor 105, which can be row electrodes, and column electrodes 140, all of which are coupled to a capacitive sensor circuit 115 and a position processor 117. The capacitor sensor circuit 115 includes an AC generator.

Coupled to the row electrodes 105 and the column electrodes 140, there are bond pads 105a-105c for the sensor (row electrode) 105, and bond pads 150a-152c for the various column electrodes 140, electrode sets 140a-140c, respectively. Basically, the FPCB 153 is bonded to the edge of sensor glass that contains the sensing network 100. A representative “X and Y” matrix is formed by 3 columns 105a, 105b and 105c, with 3 rows of electrodes 150, 151, and 152.

These bond pads 105a-105c and 150a-152c are coupled to a top metal layer 140 of a flexible printed circuit board (FPCB) layer 153. The various bond pads are coupled to the top metal layer of FPC 150 with a bonding material, and therefor coupled to the capacitive sensor circuit 115.

Sets of bonding pad sets are themselves coupled together on the bottom metal layer 180 of the flex FPCB 153 (to be illustrated later) after passing through bonding materials, the lower layer metal of FPCB 160 and vias on the lower FPCB level 160. The sensor (row) electrodes 105 and the column electrodes 140 are themselves embedded in a level of Indium Tin Oxide (ITO) , as will be illustrated in prior art FIG. 1Bii.

However, not all electrodes are shorted together: the corresponding bond pads 105a, 105b and 105c are not shorted together, and each has its own independent path to the capacitive sensor circuit 115. However, bond pads 150a, 150b and 150c are shorted, together so therefore their corresponding electrodes are shorted. Bond pads 151a/b/c are shorted to one another, and bond pads 152a/b/c are shorted to one another, but no shorting in between bond pad sets 150, 151, and 152 occurs on the bottom metal layer 180 of the FPCB 153.

The effect of the coupling on the second level is to create a “matrix” or “array” that simulates a 3-D that can read simultaneous multiple touches. As a conductive digit (such as a thumb) is brought closer to the electrodes, the capacitance between row electrodes 105 and column electrodes 140 will be modulated, which will be measured by the capacitive sensor circuit 115, and then the position of the touch will be calculated by the position processor 117.

Prior Art FIG. 1B is a side view slice of the lower metal layer 160 and the higher level metal layer 180, both of which are attached to the Flex PCB 153, which also includes a side view of the prior art capacitive sensing network 100.

A transparent cover of glass or polymer (“polymer”) 120 is a protective overlay. An optical clear adhesive (“OCA”) 129 is mounted beneath the polymer 120. A layer of ITO 123, used for the electrodes, is coupled beneath the OCA 123, and a substrate for ITO 124 is coupled beneath the ITO 123.

As is illustrated, the bonding material 105a-105c, and 150a-152c are coupled between the ITO 123 and the lower layer metal 150 on FLEX PCB 160. Coupled to the lower metal layer 160 is the dielectric substrate of flex PCB 153, and coupled to that, is the upper layer metal on flex PCB 180. The interconnections of the various sets of the electrodes occur on this upper level.

However, as appreciated by the inventor of the present application, there are drawbacks with this design. The sensing network 100 required a high bonding pad counts. For example, twelve bonding pads are required for a 3×3 mutual capacitance array, and sixty bonding pads are required by 5×10 mutual capacitance array. This high count of bonding pads is a significant disincentive for design, due to such drawbacks as problems with yield with bonding pads. Moreover, the routing of the array requires the upper metal level 180, an additional cost factor.

It would be advantageous to have a single touch sensor that addresses at least some of these drawbacks.

### SUMMARY

A first aspect provides a single touch mutual capacitive sensing that uses a tapered capacitive sensing pattern comprising a plurality of receiving electrode sets, each of the plurality of receiving electrodes being defined by a coupled intersecting diagonal bar; a plurality of sets of transmitting electrodes, each set of the transmitting electrodes having: at least a first electrode on a first side of its corresponding receiving electrode, and a second electrode on a second side of its corresponding receiving electrode; and a first AC signal generator to generate a signal on the plurality of electrode sets of transmitting electrodes to be received by the receiving electrodes.

A second aspect provides a system, comprising: a plurality of receiving electrode sets, each of the plurality of receiving electrodes being defined by a coupled intersecting diagonal bar; a plurality of sets of transmitting electrodes, each set of the transmitting electrodes having: at least a first electrode on a first side of its corresponding receiving electrode, and a second electrode on a second side of its corresponding receiving electrode; and a first AC signal generator to generate a signal on the plurality of electrode sets of transmitting electrodes to be received by the receiving electrodes; and a second AC signal generator to generate a signal on the first of the plurality of sets of transmitting electrodes to be received by the receiving electrodes.

A third aspect provides a system, comprising: a plurality of receiving electrode sets, each of the plurality of receiving electrodes being defined by a coupled intersecting diagonal bar; a plurality of sets of transmitting electrodes, each set of the transmitting electrodes having: at least a first electrode on a first side of its corresponding receiving electrode, and a second electrode on a second side of its corresponding receiving electrode; a first AC signal generator means to generate a signal on the plurality of electrode sets of transmitting electrodes to be received by the receiving electrodes, wherein the transmitting and receiving electrodes are tapered.

### BRIEF DESCRIPTION OF THE DRAWINGS

FIG. 1A is a prior art multi-touch mutual capacitive touch sensor;

FIG. 1B illustrates various layer of the prior art multi-touch mutual capacitive touch sensor;

FIG. 2A is an example tapered single touch mutual capacitive touch sensing pattern constructed according to the principles of the present disclosure;

FIG. 2B is a cut-away of the tapered single-touch mutual capacitive touch sensor;

FIG. 2C is a mobile communication device that includes the tapered single touch mutual capacitive touch sensing pattern constructed according to the principles of the present disclosure of FIG. 2A; and

FIG. 2D is a table of a summary of prior art vs. tapered single-touch mutual capacitive touch sensor.

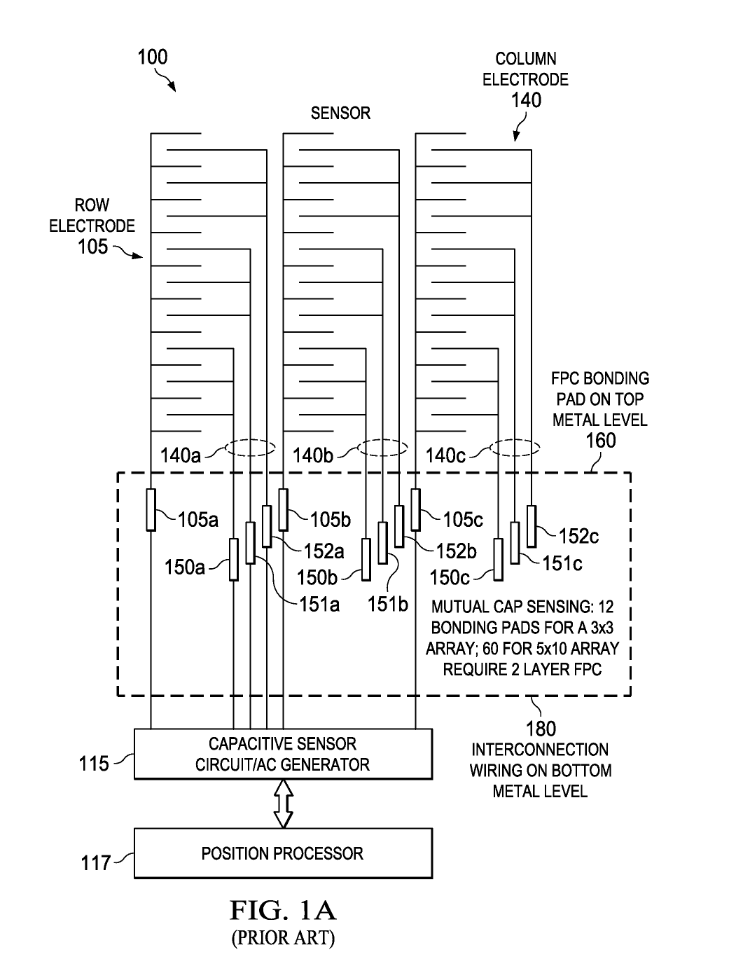

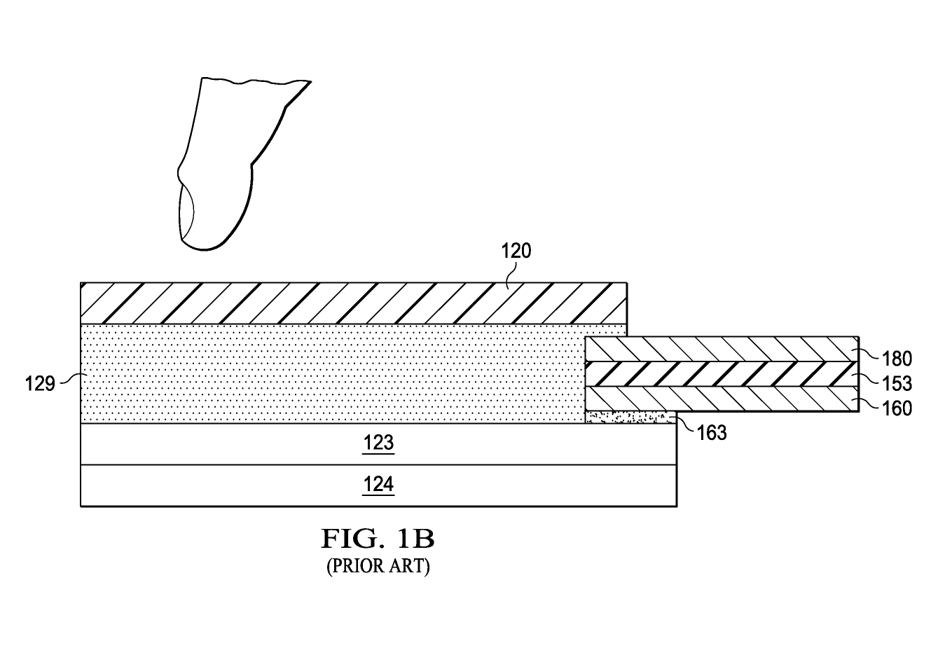

### DETAILED DESCRIPTION

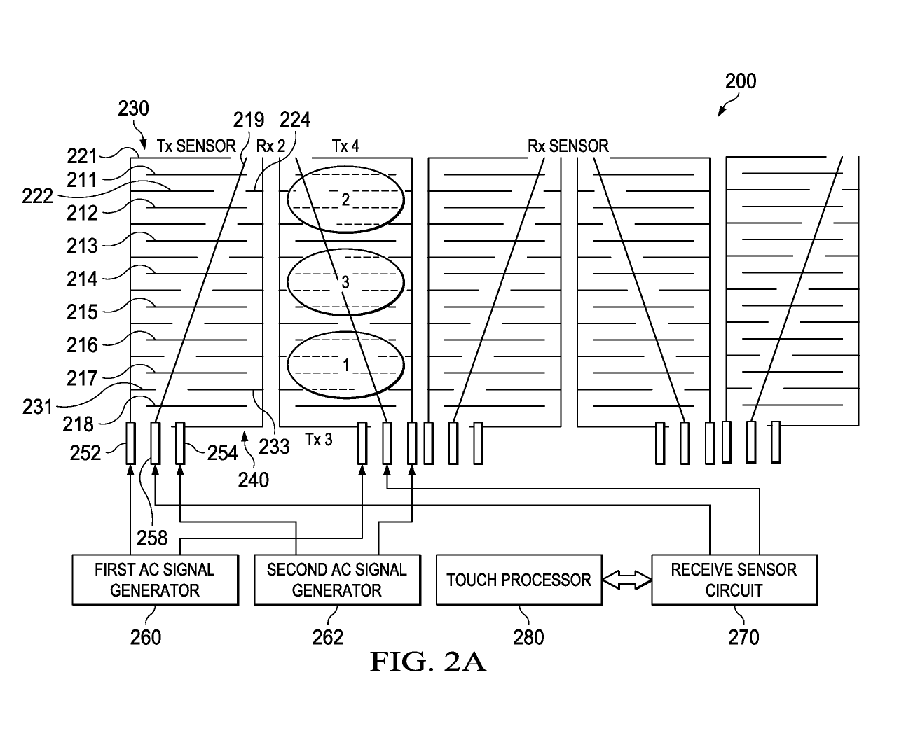

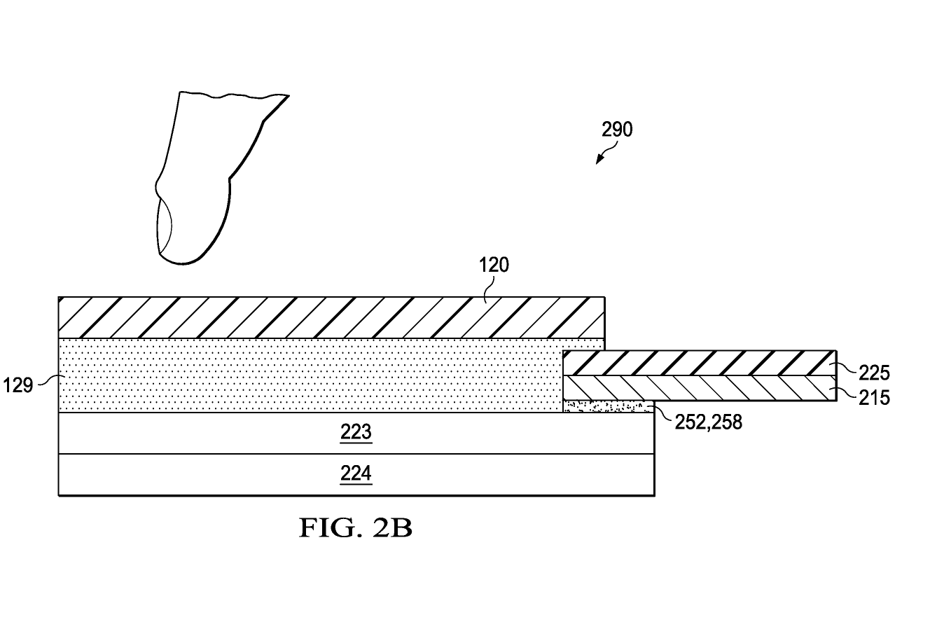

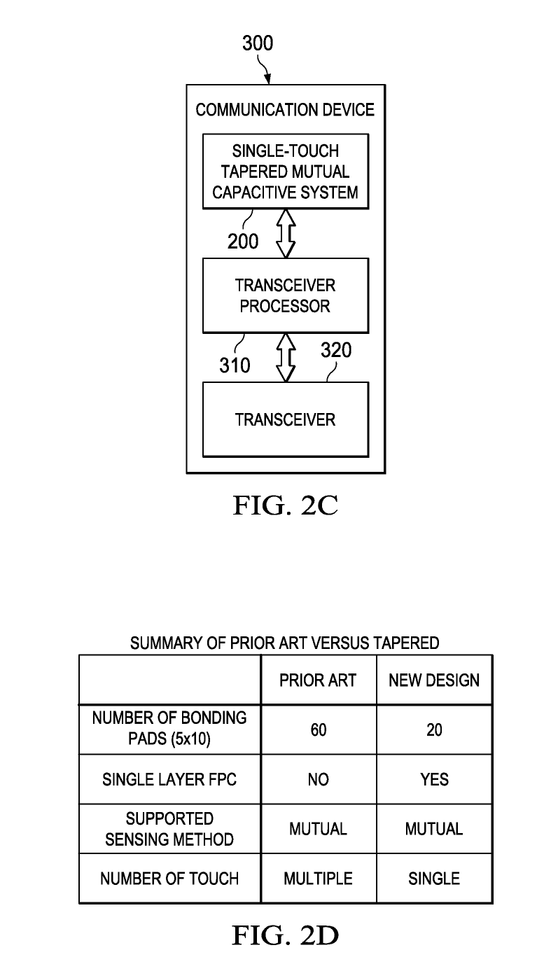

Generally, a “tapered” sensing pattern is used, such as disclosed in FIG. 2A. “Tapering” can be generally defined as the change of length various individual defined coupled electrodes along a “diagonal” receive, wherein each receive electrode length each decreases or increases as determined by a diagonal cross-wise receiver piece 219 intersecting a plurality of fixed length receiver electrodes. Moreover, the length of corresponding transmit electrodes is defined by the position of the diagonal cross-wise receiver piece 219. The transmitting electrodes and receiving electrodes are alternating.

Use of a transmit and receive sensor path in this configuration allows for the sensing of a touch with only a single FPCB layer, and with less bond pads, as compared to the prior art mutual capacitive sensing, as will be described below.

Turning to FIG. 2A, illustrated is a tapered mutual capacitive sensing system 200. In the tapered mutual capacitive sensing system 200, a series of individual ITO receive electrode strips 211-218, are each coupled by a diagonal crosswise piece 219 that intersects a transmit strip 230, breaking each transmitting electrode into a set having two parts, such as 222 and 224. This creates coupled individual received electrodes 221-224 etc., each of a different length that is defined by the diagonal cross-wise piece 219.

The transmit ITO strip 230 has individual sets of individual transmit strips 231, 233, etc. each of a different length that also correspond to the diagonal intersecting path, as does its corresponding transmit ITO strip 240. The transmit electrode strips alternate with the receive electrode strips.

Each of the transmit paths are coupled to its own respective transmit bond pad 252, 254, etc. and each receive electrode path are coupled to its own respective receive bond pad 258 etc. Although not illustrated for a sake of clarity, each transmit sensor or receive sensor path is coupled to its own bond pad.

In one aspect, all transmit bond pads are then coupled to a first AC signal generator 260. In a further aspect, as illustrated, alternating transmit bond pads are then coupled to the first AC signal generator 260 and a second AC signal generator 262, respectively.

In a first aspect, AC signals used for generating a signal for determining a mutual conductance are transmitted in sequence, not in parallel, so no need to differentiate them. In the alternative aspect, a parallel scan occurs on the pads with the first and second AC signal generators generating different AC signals, which is then distinguished by the receive sensor circuit 270.

The receive pad 258, etc. are each coupled to a receive sensor circuit 270, which measures the combined received capacitive signal from both the first and second transmit path, and the touch processor 280, which takes the measurements from the receive sensor circuit 270, and then determines a position of the touch.

For example, referring to the system 200, there are illustrated three different potential touch areas that occur at different locations on the part of a capacitive touch screen that corresponds to TX3 and TX4: touch area one, touch area two, and touch area three.

At touch area 1, the strength first AC signal of TX3/RX2 will higher than the signal strength from TX4/RX2, whereas at location 2, it is vice versa. At location three, this ratio is about unity. Therefore, the value of this ratio can be used to determine the location of finger touch.

There are numerous advantages to this “tapered design.” As is illustrated, each section of a screen only requires three bond pads: two transmit bond pads and a receive bond pad. On a typical design, this is a significant reduction of bond pads. As shown in FIG. 2D, for a 5×10 array, the reduction is from 60 to 20. Advantageously, the mutual capacitive system 200 allows for the omission of various bond pads, yet with a retention of the function of signal conveying properties of the bond pads.

Moreover, the electrodes are not directly coupled to each other. In the prior art, the electrodes were coupled to each other on the second FPCB. However, in the tapered mutual capacitance sensing system 200, there is no need of a second FPCB for this routing. Advantageously, the mutual capacitive system 200 allows for the omission of the FCPC, yet allows for a sensing of a position of a tapered capacitive mutual touch on a pad.

Furthermore, compared to the prior art system 100, the electrodes do not merely perform the function that they performed separately in the prior art. In the prior art, the electrodes were shorted into an x-y matrix. Here, the tapered electrodes are not shorted, yet they are still capable of a determination of a position of a touch without the shorting that occurs from creating an array, something that did not occur in the prior art.

As is illustrated, the system 200 has a plurality of receiving electrode sets, for example, 221, 222 and 223, 224, each of the plurality of receiving electrodes being defined by a coupled intersecting diagonal bar 219; a plurality of sets of transmitting electrodes, for example, 231, 233, 251, and 252, and each set of the transmitting electrodes having: at least a first electrode on a first side of its corresponding receiving electrode, and a second electrode on a second side of its corresponding receiving electrode; and a first AC signal generator to generate a signal on the plurality of electrode sets of transmitting electrodes to be received by the receiving electrodes.

FIG. 2B illustrates a side view of a touch screen 290 incorporating the tapered mutual capacitive system 200. The polymer 120 has an underlying ITO layer 223 having the tapered interleaving pattern and substrate 224. The ITO 223 is then coupled though the bonding material 252, 254, 258, etc. a single layer metal 215 on flex PCB, which is on the flex PCB 225. Please note, however that there is no metal layer, such as the upper metal layer of the prior art, dedicated to shorting the various electrodes to enable a mutual capacitance detection. The functionality of mutual capacitance detection occurs, without an employment of a dedicated metal layer of the FPCB.

The additional circuitry (AC generation etc.) is not shown in this figure for an ease of illustration.

FIG. 2C illustrates a communication device 300. The communication device includes the single touch tapered mutual capacitive system 200. The device 300 includes a coupled transceiver processor 310 and a transceiver 320 for communication.

FIG. 2D is a table of a summary of the various characteristics of an example prior art 100 vs. an example tapered 200 mutual inductance system.

As is illustrated for a 5 by 10 array, the prior art mutual sensing 100 used 60 bonding pads, wherein the tapered system 200 uses 20. Moreover, the bigger the touch panel, the more benefit we will see on bonding pads reduction, as there is a linear increase of bonding pads per additional segment, but a bigger screen use a power of two exponential increase in bonding pads. Moreover, prior art mutual sensing 100 required at least two layers of a flexible printed circuit board, whereas the single touch tapered mutual capacitive system 200 is enabled with only a single layer FPCB.

What is claimed is:

1. A system, comprising:
a plurality of receiving electrode sets, each of the plurality of receiving electrodes being defined by a coupled intersecting diagonal bar;
a plurality of sets of transmitting electrodes, each set of the transmitting electrodes having:
at least a first electrode on a first side of its corresponding receiving electrode, and
a second electrode on a second side of its corresponding receiving electrode; and
a first AC signal generator to generate a signal on the plurality of electrode sets of transmitting electrodes to be received by the receiving electrodes.

2. The apparatus of claim 1, wherein a total length of a corresponding first and second receiving electrode set is substantially equal.

3. The apparatus of claim 2, wherein the receiving electrode sets and the transmitting sets are fabricated from an indium titanium oxide (ITO).

4. The apparatus of claim 3, further comprising a single flexible printed circuit board coupled to the ITO.

5. The apparatus of claim 4, further comprising:
an optical clear adhesive coupled to the ITO, and
a transparent material coupled to the top of the OCA.

6. The apparatus of claim 5, wherein the transparent material is divided into a plurality of logical segments.

7. The apparatus of claim 5, wherein each logical segment comprises two transmit bond pads and a receiver bond pads coupled to the ITO.

8. A system, comprising:
a plurality of receiving electrode sets, each of the plurality of receiving electrodes being defined by a coupled intersecting diagonal bar;
a plurality of sets of transmitting electrodes, each set of the transmitting electrodes having:
at least a first electrode on a first side of its corresponding receiving electrode,
a second electrode on a second side of its corresponding receiving electrode; and
a first AC signal generator to generate a signal on the plurality of electrode sets of transmitting electrodes to be received by the receiving electrodes; and
a second AC signal generator to generate a signal on the first of the plurality of sets of transmitting electrodes to be received by the receiving electrodes

9. The system of claim 8, wherein the receiving electrodes and transmitting electrodes are coupled to a transceiver within a communication device.

10. The system of claim 9, wherein the receiving electrode sets and the transmitting sets are from an indium titanium oxide (ITO).

11. The system of claim 10, further comprising a single flexible printed circuit board coupled to the ITO.

12. The system of claim 11, further comprising an optical clear adhesive coupled to the ITO, and
a transparent material coupled to the top of the OCA.

13. The system of claim 12, wherein the transparent material is divided into a plurality of logical segments.

14. The system of claim 12, wherein each logical segment comprises two transmit bond pads and a receiver bond pads coupled to the ITO.

15. A system, comprising:
a plurality of receiving electrode sets, each of the plurality of receiving electrodes being defined by a coupled intersecting diagonal bar;
a plurality of sets of transmitting electrodes, each set of the transmitting electrodes having:
at least a first electrode on a first side of its corresponding receiving electrode, and
a second electrode on a second side of its corresponding receiving electrode;
a first AC signal generator means to generate a signal on the plurality of electrode sets of transmitting electrodes to be received by the receiving electrodes,
wherein the transmitting and receiving electrodes are tapered.

16. The system of claim 15, wherein the receiving electrode sets and the transmitting sets are fabricated from an indium titanium oxide (ITO).

17. The system of claim 16, further comprising a single flexible printed circuit board coupled to the ITO.

18. The system of claim 17, further comprising:
an optical clear adhesive coupled to the ITO, and
a transparent material coupled to the top of the OCA.

19. The system of claim 18, wherein the transparent material is divided into a plurality of logical segments.

20. The system of claim 18, wherein each logical segment comprises two transmit bond pads and a receiver bond pads coupled to the ITO.
